(19) United States
(12) Patent Application Publication
(10) Pub. No.: US 2016/0044805 A1
(43) Pub. Date: Feb. 11, 2016

(54) PORTABLE DEVICE HOLDER WITH MIRROR

(71) Applicant: Eagle FAN, Chu-Pei City (TW)

(72) Inventor: Eagle FAN, Chu-Pei City (TW)

(21) Appl. No.: 14/453,103

(22) Filed: Aug. 6, 2014

(51) Int. Cl. H05K 5/02; A47G 1/16; A45C 1/12; H05K 5/00

(52) U.S. Cl. CPC H05K 5/0204; H05K 5/0086; A47G 1/16; A45C 1/12

(57) ABSTRACT

An exemplary embodiment describes a portable device holder with mirror, including a base unit, at least a stop element and a minor. The base unit includes a placement surface for placing a portable electronic device. The minor is disposed on the placement surface and occupies at least a part of the placement surface. The stop element is disposed at the base unit and protrudes beyond from underneath the placement surface. When the portable device is placed on the placement surface, the stop element is located at an edge of the portable device to prevent the portable device from falling off the placement surface. After the portable device is removed from the placement surface, the minor disposed to cover the placement surface is exposed and is used as a mirror. As such, the present invention can be used as a device holder and a mirror.

### TECHNICAL FIELD

The technical field generally relates to a portable device holder, in particular, to a holder for holding a portable device and having a base disposed with a minor.

### BACKGROUND

A product must satisfy at least a practical need as well as creating desirability to stay competitive in a modern consumer market. A conventional portable device holder is usually designed with a structure to provide support to a portable electronic device, such as smart phone or tablet PC, to stand conveniently on a surface, such as a desk top or a top of the dashboard in a car. The portable device holder allows the user hand-free convenience to conduct other operations. However, as the surface space becomes more limited and many functional devices are competing for surface space, it is imperative to devise multi-functional device holder to provide more convenience to the device users.

### SUMMARY

The object of the present disclosure is to provide a portable device holder with minor so that the portable device holder can be used as a minor when not holding a portable device.

An exemplary embodiment describes a portable device holder with mirror, including a base unit, at least a stop element and a minor. The base unit includes a placement surface for placing a portable electronic device. The mirror is disposed on the placement surface and occupies at least a part of the placement surface. The stop element is disposed at the base unit and protrudes beyond from underneath the placement surface. When the portable device is placed on the placement surface, the stop element is located at an edge of the portable device to prevent the portable device from falling off the placement surface. After the portable device is removed from the placement surface, the minor disposed to cover the placement surface is exposed and is used as a minor.

Another exemplary embodiment describes the portable device holder with minor as further including two clamping units. The two clamping units are disposed on two opposite sides of the base unit, with at least one of the two clamping units able to move toward and away from the other clamping unit. In a clamping state, the portable device is clamped between the two clamping units so that the stop element and the two clamping units contact three sides of the portable device to hold the portable device in position.

The foregoing will become better understood from a careful reading of a detailed description provided herein below with appropriate reference to the accompanying drawings.

### BRIEF DESCRIPTION OF THE DRAWINGS

The embodiments can be understood in more detail by reading the subsequent detailed description in conjunction with the examples and references made to the accompanying drawings, wherein:

FIG. 1 shows a schematic view of a first exemplary embodiment of the present invention;

FIG. 2 shows a cross-sectional view of the first exemplary embodiment of the present invention;

FIG. 3 shows a schematic view of a second exemplary embodiment of the present invention;

FIG. 4 shows a schematic view of the movement of the clamping units of the second exemplary embodiment;

FIG. 5 shows a schematic view of a third exemplary embodiment of the present invention; and

FIG. 6 shows a schematic view of the movement of the auxiliary clamping element of the third exemplary embodiment.

### DETAILED DESCRIPTION OF THE DISCLOSED EMBODIMENTS

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

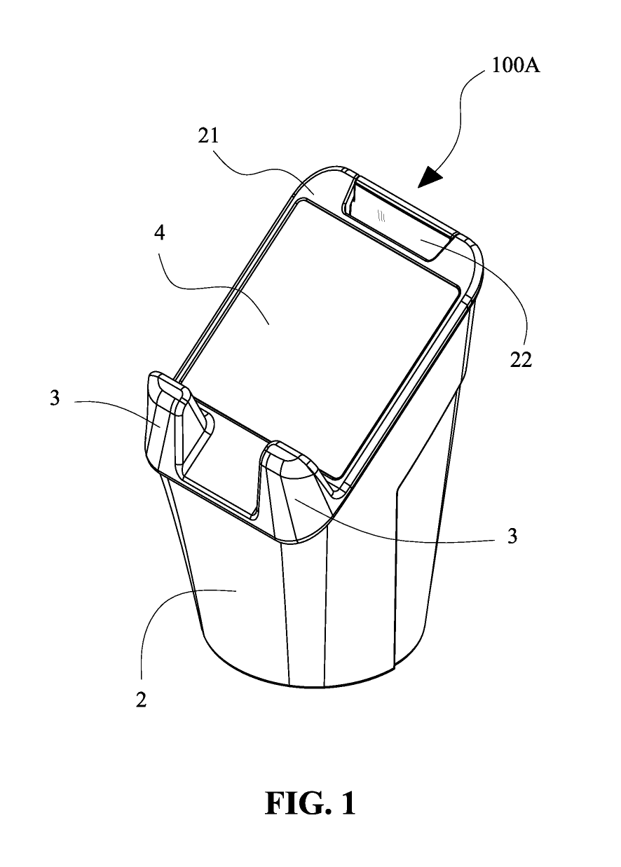

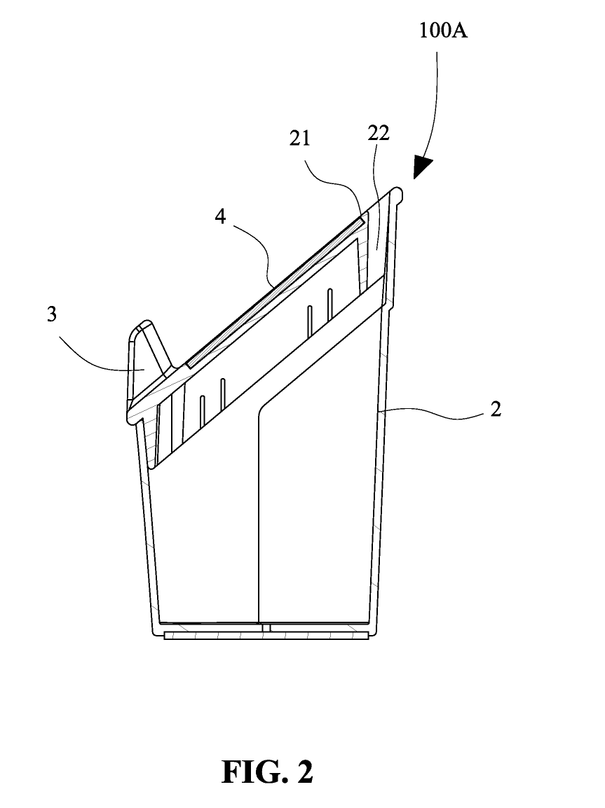

FIG. 1 and FIG. 2 show a schematic view and a cross-sectional view of the first embodiment of the present invention respectively. A portable device holder 100A is to provide a surface for a portable device to be placed in a leaning position. The portable device holder 100A includes a base unit 2, at least a stop element 3 and a mirror 4. The base unit 2 has a rectangular shape with a thickness, and includes a placement surface 21. The placement surface 21 is at a top surface of the base unit 2 and shows a slant flat surface for placing a portable device. A part of the placement surface is disposed with the minor 4. In the instant embodiment, the minor 4 has a width close to the width of the placement surface 21 and a length shorter than the length of the placement surface 21. The minor 4 may be made of glass or plastic. The stop element 3 is disposed at the base unit 2 and protrudes beyond the placement surface 21. In the instant embodiment, the stop element 3 is at the lower edge of the slant placement surface 21. When the portable device is placed on the placement surface 21, the stop element 3 contacts the lower edge of the portable device to prevent the portable device from falling off placement surface.

The base unit 2 in the instant embodiment is a rectangular hollow box, which may also serve as a piggybank to hold coins. The base unit 2 includes a coin slot 22, which is located at the top of the base unit 2 in the instant embodiment. As such, the portable device holder 100A of the embodiment provides three functions. When not holding a portable device, portable device holder may be used as a conventional mirror as well as a coin holder.

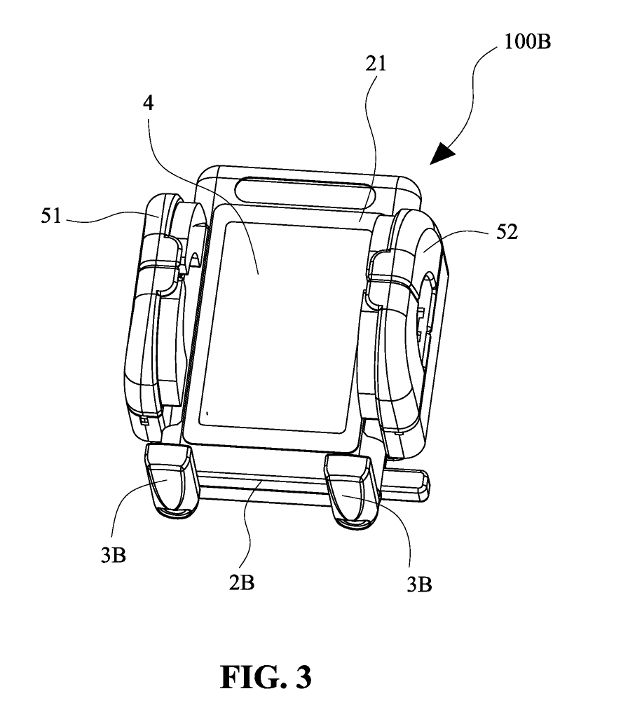

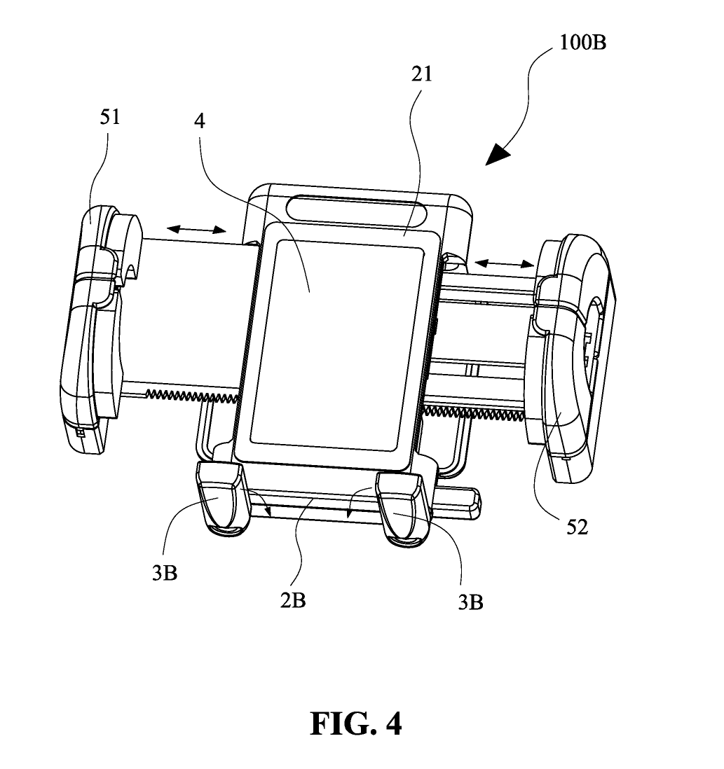

FIG. 3 and FIG. 4 show a schematic view of the second embodiment and a schematic view of the movement of the clamping units respectively. A portable device holder 100B includes a base unit 2B, at least a stop element 3B and a mirror 4; the portable device holder 100B further includes two clamping units 51, 52; wherein the two clamping units 51, 52 are disposed at two opposite sides of the base unit 2B. At least one of the two clamping units 51, 52 is able to move toward and away from the other clamping unit. In this embodiment, the two clamping units 51, 52 are able to move toward and away from each other synchronously. In a clamping state, the portable device is clamped between the clamping units 51, 52, so that the stop element 3B and the clamping units 51, 52 contact the three sides of the portable device to hold the portable device in position. The stop element 3B may rotate for easy storage to the side of the base unit 2B. The inside of the base unit 2B further includes linkage mechanism to actuate the synchronous movement of the clamping units, which is similar to known technique and will not be described in details. In this embodiment, the minor 4 is also disposed on a part surface of the placement surface 21. The portable device holder 100B must employ other auxiliary support structure, such as, suction disk or sand-bag support, so that the portable device holder 100B can be fastened to a surface inside a vehicle.

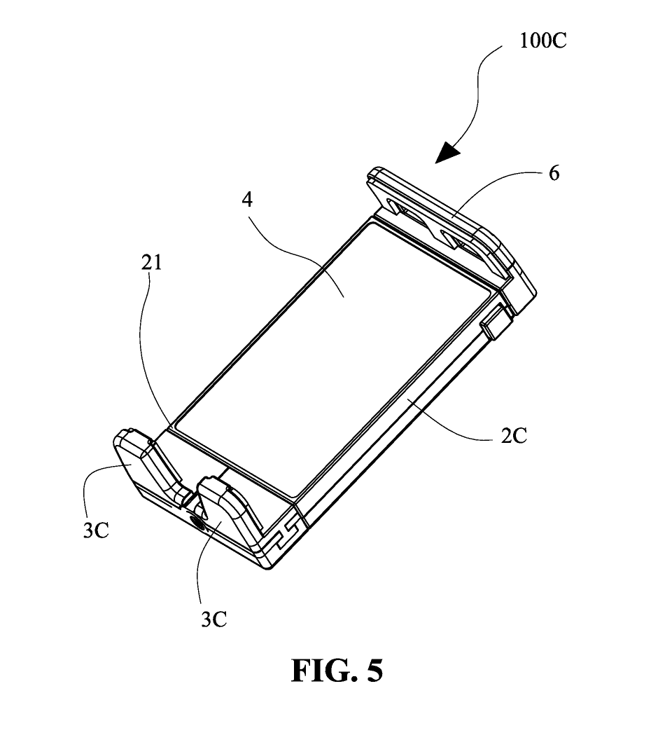

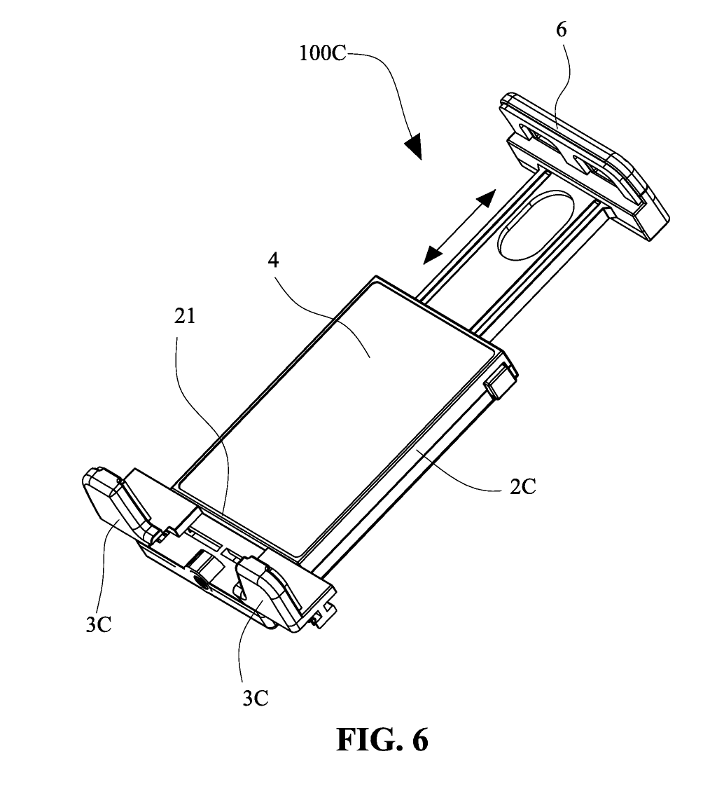

FIG. 5 and FIG. 6 shows the third embodiment of the present invention. In this embodiment, the portable device holder 100C includes a base unit 2C, at least a stop element 3C, a minor 4, and an auxiliary clamping element 6. The stop element 3C and the auxiliary clamping element 6 are located at two opposite sides of the base unit 2C, wherein the auxiliary clamping element 6 is able to move forward and away from the stop element 3C. In the clamping state, the portable device is clamped between the stop element 3C and the auxiliary clamping element 6. In another embodiment, the stop element 3C may also be adjusted laterally. The structure of the portable device holder 100C in the third embodiment is suitable for holding larger size device, such as a tablet PC.

In summary, the portable device holder with minor is to provide a mirror disposed at the surface for placing the portable device, and when the portable device is removed from the portable device holder, the portable device holder can also be used as a minor.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A portable device holder with mirror, comprising:
a base unit,
at least a stop element and
a mirror;
wherein the base unit having a placement surface for placing a portable device;
the mirror being disposed on the placement surface and occupying at least a part of the placement surface;
the stop element being disposed at the base unit and protruding beyond from underneath the placement surface;
when the portable device being placed on the placement surface, the stop element being located at an edge of the portable device to prevent the portable device from falling off the placement surface; and
after the portable device being removed from the placement surface, the mirror disposed to cover the placement surface being exposed and is used as a mirror,
further comprising
two clamping units, disposed at two opposite sides of the base unit, with at least one of the two clamping units able to move toward and way from the other clamping unit;
in a clamping state, the portable device being clamped between the two clamping units so that the stop element and the two clamping units contacting three sides of the portable device to hold the portable device in position.

2. The portable device holder with mirror as claimed in claim 1, wherein the base unit is a rectangular hollow box with a coin slot so that the portable device holder also serves as coin storage.

3. (canceled)

4. A portable device holder with mirror comprising:
a base unit,
at least a stop element and
a mirror;
wherein the base unit has a placement surface for placing a portable device;
the mirror being disposed on the placement surface and occupying at least a part of the placement surface;
the stop element being disposed at the base unit and protruding beyond from underneath the placement surface;
when the portable device is placed on the placement surface, the stop element is located at an edge of the portable device to prevent the portable device from falling off the placement surface; and
after the portable device is removed from the placement surface, the mirror is disposed to cover the exposed placement surface and is used as a mirror, further comprising
an auxiliary clamping element, the stop element and the auxiliary clamping element being disposed at two opposite sides of the base unit and the auxiliary clamping element being able to move toward and away from the stop element;
in a clamping state, the portable device being clamped between the stop element and the auxiliary clamping element.

5. The portable device holder with mirror as claimed in claim 4, wherein the base unit is a rectangular hollow box with a coin slot so that the portable device holder also serves as coin storage.
